(19) United States
(12) Patent Application Publication
(10) Pub. No.: US 2025/0054277 A1
(43) Pub. Date: Feb. 13, 2025

(54) SYSTEM FOR CONSTRUCTING DEFECT LEVEL CLASSIFICATION MODEL

(71) Applicant: JADE BIRD DISPLAY (SHANGHAI) LIMITED, SHANGHAI (CN)

(72) Inventors: Chenchao XU, Shanghai (CN); Yang YUE, Shanghai (CN); Qiming LI, Shanghai (CN)

(21) Appl. No.: 18/719,839

(22) PCT Filed: Dec. 16, 2021
(86) PCT No.: PCT/CN2021/138835

§ 371 Date: Jun. 14, 2024

(51) Int. Cl. G06V 10/764; G06T 7/00; G06V 10/32; G06V 10/60

(52) U.S. Cl. CPC G06V 10/764; G06T 7/0002; G06V 10/32; G06V 10/60; G06T 2207/30148

(57) ABSTRACT

A method of constructing a defect level classification model of a micro LED array panel includes: defining a defect classification rule for classifying pixel defects; detecting a pixel defect of the micro LED array panel; identifying a pixel defect type of the detected pixel defect according to the defect classification rule; and, identifying a defect level of the micro LED array panel according to a defect level classification rule and the identified pixel defect type.

### FIELD OF THE DISCLOSURE

The present disclosure generally relates to a light emitting diode technology field and, more particularly, to a system for constructing defect level classification model of a micro light emitting diode (LED) array panel.

### BACKGROUND OF THE DISCLOSURE

Micro LEDs with extra small areas and high resolutions are increasingly popular in the world. A micro LED array panel can be used to form various kinds of devices, such as camera module, projection modules, display modules, VR/AR optical modules and so on.

However, because a light emitting area and an image displayed by the micro LED array panel are much smaller than before, pixel defects of the micro LED array panel are not easy to be detected and identified by the conventional methods. Thus, operators need to review a wafer, a chip, and a mask through a graphical user interface displaying various patterns of the micro LED array panel, so as to identify the pattern defects.

Unfortunately, defect classification of the micro LED array panel has not performed before. Since the micro LED array pixels have extra small dimension and space, the integration of the pixels in a certain area is highly increased, compared with the conventional LED pixels. The defect detection process is not accurate and time consuming.

As such, it would be advantageous to provide a method that provides defect classification of the micro LED array, defect type separability, and classification monitoring, to improve the defect detection accuracy and decrease the process time.

The above content is only used to assist in understanding the technical solutions of the present application and does not constitute an admission that the above is prior art.

### BRIEF SUMMARY OF THE DISCLOSURE

In order to overcome the drawback mentioned above, the present disclosure provides a method for constructing a defect level classification model of the micro LED array panel, to improve the defect detection accuracy.

To achieve the above objective, the method of constructing a defect level classification model of a micro LED array panel according to the present disclosure, comprising:
step 01, defining a defect classification rule for classifying pixel defects;
step 02, detecting a pixel defect of the micro LED array panel;
step 03, identifying a pixel defect type of the detected pixel defect according to the defect classification rule; and,
step 04, identifying a defect level of the micro LED array panel according to a defect level classification rule and the identified pixel defect type.

In some embodiments, according to the defect classification rule, pixel defect types at least comprise: a pixel point defect;
wherein, the pixel point defect comprises:
a dead pixel with a pixel brightness less than a dead pixel threshold;
a dark pixel with a pixel brightness less than a dark pixel threshold and larger than the dead threshold;
an over-bright pixel with a pixel brightness larger than a brightness threshold;
a normal pixel with a pixel brightness between the dark pixel threshold and the brightness threshold.

In some embodiments, according to the defect classification rule, the pixel defect types further comprises: a local area defect;
wherein, the local area defect comprises: a one-dimensional defect and a two-dimensional defect.

In some embodiments, the one-dimensional defect comprises: a line of the dead pixels with the number of the dead pixels being more than a first preset number, a line of the dark pixels with the number of the dark pixels being more than a second preset number, and a line of the over-bright pixels with the number of the over-bright pixels being more than a third preset number.

In some embodiments, the one-dimensional defect further comprises: a bad line of the pixel point defects, with the number of the pixel point defects being more than a fourth preset number.

In some embodiments, the two-dimensional defect comprises: a planar defect; the planar defect comprises multiple pixel point defects in multiple rows or multiple columns of the micro LED pixel array.

In some embodiments, the two-dimensional defect further comprises a defect that has a point defect density in a certain area or in the whole area of a micro LED array included in the micro LED array panel.

In some embodiments, the defect classification rule at least comprises a global brightness defect; the global brightness defect comprises the following state: a brightness of a light emitting area of the micro LED array panel is less than a preset global brightness threshold; or, the whole micro LED array panel is uncontrollable or undrivable.

In some embodiments, the global brightness defect further comprises: an uncontrollable pixel.

In some embodiments, the uncontrollable pixel comprises a constantly bright pixel and an undrivable pixel.

In some embodiments, the process of detecting the pixel defect of the micro LED array panel comprises: a global brightness determining process and a multiple image collecting process of collecting multiple images.

In some embodiments, the process of detecting the pixel defect of the micro LED array panel further comprises: a normalizing process according to the multiple images.

In some embodiments, the process of detecting the pixel defect of the micro LED array panel further comprises: determining whether a global brightness of the micro LED array panel reaches or exceeds a preset global brightness threshold; if NO, performing the multiple image collecting process; if YES, identifying the pixel defect type according to the pixel defect classification rule.

In some embodiments, the identifying the defect level of the micro LED array panel further comprises: identifying a defect level of each one of multiple micro LED array panels, and acquiring a defect level distribution of the multiple micro LED array panels.

In some embodiments, according to the defect level classification rule, defect levels comprise:
Level 1, in which the micro LED array panel comprises a global brightness defect; or, a pixel point defect rate of the micro LED array panel is more than a first threshold; wherein, the pixel point defect rate is as follows: the number of pixel point defects/a total number of pixels;
Level 2, in which the micro LED array panel comprises a first local area defect; or, the pixel point defect rate of the micro LED array panel is more than a second threshold;
Level 3, in which the micro LED array panel comprises a second local area defect; or, the pixel point defect rate of the micro LED array panel is more than a third threshold; wherein, a characteristic value of the first local area defect is more than a characteristic value of the second local area defect;
Level 4, in which the pixel point defect rate of the micro LED array panel is more than a fourth threshold; and,
Level 5, in which the pixel point defect rate of the micro LED array panel is less than a fourth threshold; wherein, the first threshold, the second threshold, the third threshold, the fourth threshold and the fifth threshold sequentially become smaller.

In some embodiments, the step 04 further comprises: comprising the detect pixel defect and the pixel defect type of the micro LED array panel against the defect levels until one of defect levels is determined to match the detect pixel defect and the pixel defect type.

In some embodiments, the pixel point defect rate is a dead pixel rate; or a rate of dead pixels and dark pixels;
the first local area defect at least comprises a first point defect density in a certain area or in the whole LED array area; and, the second local area defect at least comprises a second point defect density in a certain area or in the whole LED array area.

In some embodiments, the first point defect density is not less than 4 times of the second point defect density.

In some embodiments, the first threshold is not more than 50%; the second threshold is 1/50˜ 1/10 of the first threshold; the third threshold is 1/20˜ 1/10 of the second threshold and the fourth threshold is 1/20˜ 1/10 of the second threshold.

Many other advantages and features of the present disclosure will be further understood by the following detailed descriptions and the appended drawings.

### BRIEF DESCRIPTION OF THE DRAWINGS

FIG. 1 is a flow chat illustrating method of constructing a defect level classification model of the micro LED array panel according to an embodiment of the present disclosure; and

FIG. 2 is a schematic list illustrating the defect levels according to an embodiment of the present disclosure.

### DETAILED DESCRIPTION OF THE EMBODIMENTS

Reference will now be made in detail to the present preferred embodiments to provide a further understanding of the disclosure. The specific embodiments and the accompanying drawings discussed are merely illustrative of specific ways to make and use the disclosure, and do not limit the scope of the disclosure or the appended claims.

A method of detecting defect of a micro LED array panel is disclosed in the present disclosure. The micro LED array panel can be applied in the display field, the projector field, the scanning filed and so on. The micro LED herein can be in-organic LED or organic LED. For example, the dimension of the micro LED panel is about 5 mm×5 mm. The micro LED array panel comprises a micro LED array and an IC back plane formed on the back of the micro LED array. It is noted that, the “back” herein refers to a direction opposite to a light emitting direction. The micro LED array can be any pixel matrix, such as, 1600×1200, 680×480, 1920×1080 and so on. The light emitting area of the micro LED array panel 00 is very small, such as 3 mm*5 mm. It is noted that, the light emitting area is the area of the micro LED array. The diameter of the micro LED is in the range about 200 nm˜2 μm. An IC back plane is formed at the back surface of the micro LED array and electrically connected with the micro LED array. The IC back plane acquires signals such as image data from outside via signal lines to control a corresponding micro LED to emit light. The IC back plane generally employs an 8-bit Digital to analog converter (DAC). The 8-bit DAC has 256 levels of manifestations, and each level corresponds to one gray level, that is, the 8-bit DAC may provide 256 different gray levels. Since any one of the 256 gray levels may be applied on the micro LED, a gray level ranging from 0 to 255 may be displayed by one pixel. Optionally, a brightness value of the micro LED can be controlled by voltage amplitudes or current amplitudes of the signals acquired by the IC back plane, while the gray levels can be shown by time intervals, e.g., pulse widths, of the signals.

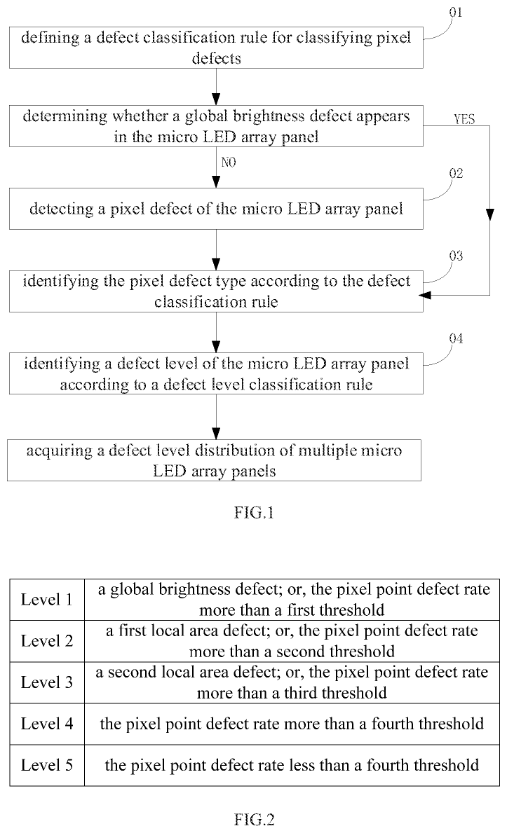

Referring to FIG. 1, disclosed herein is a method of constructing a defect level classification model of a micro LED array panel, comprising:

Step 01: defining a defect classification rule for classifying pixel defects;

Herein, the defect classification rule classifies pixel defects into a plurality of pixel defect types. The pixel defect types at least comprise: a pixel point defect; wherein, the pixel point defect comprises: a dead pixel with a pixel brightness less than a dead pixel threshold; a dark pixel with a pixel brightness less than a dark pixel threshold and larger than the dead threshold; an over-bright pixel with a pixel brightness larger than a brightness threshold; and, a normal pixel with a pixel brightness between the dark pixel threshold and the brightness threshold.

Additionally, according to the defect classification rule, the pixel defect types further comprise: a local area defect; wherein, the local area defect comprises: a one-dimensional defect, and a two-dimensional defect. The one-dimensional defect comprises: a line of the dead pixels with the number of the dead pixels being more than a first preset number, a line of the dark pixels with the number of the dark pixels being more than a second preset number, and a line of the over-bright pixels with the number of the over-bring pixels being more than a third preset number. The one-dimensional defect may further comprise: a bad line of pixel point defects, with the number of the pixel point defects being more than a fourth preset number. The two-dimensional defect comprises: a planar defect; the planar defect comprises multiple pixel point defects in multiple rows or multiple columns of the micro LED pixel array. It is noted that, the first preset number, the second preset number, the third preset number, and the fourth preset number can be determined according to an actual process and will not be limited herein. Additionally, the two-dimensional defect may further comprises a defect that has a point defect density in a certain area or in the whole area of a micro LED array included in the micro LED array panel.

Furthermore, according to the defect classification rule, the pixel defect types further comprise a global brightness defect; the global brightness defect comprises: the brightness of the light emitting area of the micro LED array panel is less than a preset global brightness threshold; or the whole micro LED array panel is uncontrollable or undrivable; or, at least one pixel is an uncontrollable pixel. Wherein, the uncontrollable pixel comprises a constant brightness pixel and an undrivable pixel.

Step 02: detecting a pixel defect of the micro LED array panel;

Herein, the process of detecting pixel defect of the micro LED array panel comprises: a global brightness determining process and multiple image collecting process. Herein, before detecting the pixel defect of the micro LED array panel, the method further comprises: determining whether a global brightness defect appears in the micro LED array panel, if No, performing the step 02 of the defect detecting process. It is noted that, the global brightness defect can be recognized by human eyes or a computer recognizing system. Herein, the preset global brightness threshold can be depended on the actual application and will not be limited herein. If the global brightness defect appears in the micro LED array panel, the defect detecting process step 02 will not be performed and the step 03 is performed. Furthermore, the global brightness determining process comprises: determining whether a global brightness of the micro LED array panel reaches or exceeds a preset global brightness threshold; if No, performing the multiple image collecting process; if Yes, performing the step 03, identifying a pixel defect type according to the pixel defect classification rule.

The multiple image collecting process comprises collecting multiple pattern images of the micro LED array by switching on different LED patterns every time. Herein, the number of the pattern images can be two or more than two. It is noted that, the LEDs in every pattern image can be switched on once or more. In each pattern image, at least one or more LEDs are turned off between the adjacent LEDs switched on. After the image collecting process, a normalizing process is further performed according to the multiple images. The normalizing process can be understood by those skilled in the art, which will not be described herein. After collecting the multiple pattern images of the micro LED array, one or more pixel defects may be detected according to the pattern images.

Step 03: identifying a type of the pixel defect according to the defect classification rule; and,

step 04: identifying a defect level of the micro LED array panel according to a defect level classification rule.

Herein, the step 04 further comprises: identifying a defect level in each one of multiple micro LED array panels; and then, acquiring a defect level distribution of the multiple micro LED array panels.

Referring to FIG. 2, according to the defect level classification rule, a micro LED array panel disclosed herein may have one of a plurality of possible defect levels. The defect levels comprise: Level 1 in which the micro LED array panel comprises a global brightness defect; or, a pixel point defect rate of the micro LED array panel is more than a first threshold; wherein, the pixel point defect rate is defined as a ratio between a pixel point defect number and a total pixels number; Level 2 in which the micro LED array panel comprises a first local area defect; or, the pixel point defect rate of the micro LED array panel is more than a second threshold; Level 3 in which the micro LED array panel comprises a second local area defect; or, the pixel point defect rate of the micro LED array panel is more than a third threshold; wherein, a characteristic value (e.g., density) of the first local area defect is more than a characteristic value (e.g., density) of the second local area defect; Level 4 in which the pixel point defect rate of the micro LED array panel is more than a fourth threshold; Level 5 in which the pixel point defect rate of the micro LED array panel is less than a fourth threshold; wherein, the first threshold, the second threshold, the third threshold and the fourth threshold sequentially become smaller. The pixel point defect rate can be a dead pixel rate; or a rate of the dead pixel and the dark pixel. Wherein, the dead pixel rate is equal to: the dead pixel number/the total pixels number; the rate of the dead pixel and the dark pixel is equal to: (the dead pixel number+the dark pixel number)/the total pixels number.

Identifying the defect level in the micro LED array panel further comprises: comparing the detected pixel defect and the pixel defect type of the micro LED array panel against Level 1 to Level 5, until one of Level 1 to Level 5 is determined to match the detected pixel defect and the pixel defect type. Preferably, the first threshold is not more than 50%, preferably 20˜30%; the second threshold is 1/50˜ 1/10 of the first threshold; the third threshold is 1/20˜ 1/10 of the second threshold; the third threshold is 1/20˜ 1/10 of the second threshold; the fourth threshold is 1/20˜ 1/10 of the second threshold. For example, Level 1 indicates that the micro LED array panel comprise a global brightness defect; or, the pixel point defect rate of the micro LED array panel is more than 20%; wherein, the pixel point defect rate is the ratio between the pixel point defect number and the total pixels number; Level 2 indicates that the micro LED array panel comprises a first local area defect; or, the pixel point defect rate of the micro LED array panel is more than 1%; Level 3 indicates that the micro LED array panel comprises a second local area defect; or, the pixel point defect rate more than 0.1%; furthermore, in level 3, the dead pixel rate is not less than 0.1%; or, the defect density is more than 0.4%, or, the rate of the dead pixel and the dark pixel is not less than 1.2%; wherein, the number of the first local area defect is more than that of the second local area defect; Level 4 indicates that the pixel point defect rate of the micro LED array panel is more than 0.01%; and, Level 5 indicates that the pixel point defect rate of the micro LED array panel is less than 0.01%.

It is noted that, the first local area defect at least comprises a first point defect density in a certain area or in the whole LED array area. The second local area defect at least comprises a second point defect density in a certain area or in the whole LED array area. The first point defect density is not less than 4 times of the second point defect density. Preferable, the first point defect density is not less than 0.4%; and, the second point defect density is not less than 0.1%.

It is noted that, if a micro LED array panel includes any other defect except for the aforementioned defects, the defect level of the micro LED array panel will be classified into the level 3. If a micro LED array panel includes the defect mentioned in the above-described levels 1˜5, the defect will be classified into the corresponding level.

The above descriptions are merely embodiments of the present disclosure, and the present disclosure is not limited thereto. A modifications, equivalent substitutions and improvements made without departing from the conception and principle of the present disclosure shall fall within the protection scope of the present disclosure.

1. A method of constructing a defect level classification model of a micro LED array panel, comprising:
step 01, defining a defect classification rule for classifying pixel defects;
step 02, detecting a pixel defect of the micro LED array panel;
step 03, identifying a pixel defect type of the detected pixel defect according to the defect classification rule; and,
step 04, identifying a defect level of the micro LED array panel according to a defect level classification rule and the identified pixel defect type.

2. The method according to claim 1, wherein, according to the defect classification rule, pixel defect types at least comprise: a pixel point defect;
wherein, the pixel point defect comprises:
a dead pixel with a pixel brightness less than a dead pixel threshold;
a dark pixel with a pixel brightness less than a dark pixel threshold and larger than the dead threshold;
an over-bright pixel with a pixel brightness larger than a brightness threshold; and
a normal pixel with a pixel brightness between the dark pixel threshold and the brightness threshold.

3. The method according to claim 2, wherein, according to the defect classification rule, the pixel defect types further comprises: a local area defect;
wherein, the local area defect comprises: a one-dimensional defect and a two-dimensional defect.

4. The method according to claim 3, wherein, the one-dimensional defect comprises: a line of the dead pixels with the number of the dead pixels being more than a first preset number, a line of the dark pixels with the number of the dark pixels being more than a second preset number, and a line of the over-bright pixels with the number of the over-bright pixels being more than a third preset number.

5. The method according to claim 4, wherein, the one-dimensional defect further comprises: a bad line of the pixel point defects, with the number of the pixel point defects being more than a fourth preset number.

6. The method according to claim 4, wherein, the two-dimensional defect comprises: a planar defect; the planar defect comprises multiple pixel point defects in multiple rows or multiple columns of the micro LED pixel array.

7. The method according to claim 6, wherein, the two-dimensional defect further comprises a defect that has a point defect density in a certain area or in the whole area of a micro LED array included in the micro LED array panel.

8. The method according to claim 1, wherein, the defect classification rule at least comprises a global brightness defect; the global brightness defect comprises the following state: a brightness of a light emitting area of the micro LED array panel is less than a preset global brightness threshold; or, the whole micro LED array panel is uncontrollable or undrivable.

9. The method according to claim 8, wherein, the global brightness defect further comprises: an uncontrollable pixel.

10. The method according to claim 9, wherein, the uncontrollable pixel comprises a constantly bright pixel and an undrivable pixel.

11. The method according to claim 1, wherein, the process of detecting the pixel defect of the micro LED array panel comprises: a global brightness determining process and a multiple image collecting process of collecting multiple images.

12. The method according to claim 11, wherein, the process of detecting the pixel defect of the micro LED array panel further comprises: a normalizing process according to the multiple images.

13. The method according to claim 11, wherein, the process of detecting the pixel defect of the micro LED array panel further comprises: determining whether a global brightness of the micro LED array panel reaches or exceeds a preset global brightness threshold; if NO, performing the multiple image collecting process; if YES, identifying the pixel defect type according to the pixel defect classification rule.

14. The method according to claim 1, wherein, the identifying the defect level of the micro LED array panel further comprises: identifying a defect level of each one of multiple micro LED array panels, and acquiring a defect level distribution of the multiple micro LED array panels.

15. The method according to claim 1, wherein, according to the defect level classification rule, defect levels comprise:
Level 1, in which the micro LED array panel comprises a global brightness defect; or, a pixel point defect rate of the micro LED array panel is more than a first threshold; wherein, the pixel point defect rate is as follows: the number of pixel point defects/a total number of pixels.

16. The method according to claim 15, wherein, the pixel point defect rate is a dead pixel rate; or a rate of dead pixels and dark pixels.

17. The method according to claim 15, wherein, defect levels further comprise Level 2, in which the micro LED array panel comprises a first local area defect; or, the pixel point defect rate of the micro LED array panel is more than a second threshold.

18. The method according to claim 17, wherein, the first local area defect at least comprises a first point defect density in a certain area or in the whole LED array area.

19. The method according to claim 17, wherein, defect levels further comprise Level 3, in which the micro LED array panel comprises a second local area defect; or, the pixel point defect rate of the micro LED array panel is more than a third threshold; wherein, a characteristic value of the first local area defect is more than a characteristic value of the second local area defect.

20. The method according to claim 19, wherein, the second local area defect at least comprises a second point defect density in a certain area or in the whole LED array area.

21. The method according to claim 19, wherein, defect levels further comprise Level 4, in which the pixel point defect rate of the micro LED array panel is more than a fourth threshold.

22. The method according to claim 21, wherein, defect levels further comprise Level 5, in which the pixel point defect rate of the micro LED array panel is less than a fourth threshold; wherein, the first threshold, the second threshold, the third threshold and the fourth threshold sequentially become smaller.

23. The method according to claim 15, wherein, the step 04 further comprises: identifying the detect pixel defect and the pixel defect type of the micro LED array panel against defect levels until one of defect levels is determined to match the detect pixel defect and the pixel defect type.

24. The method according to claim 19, wherein, the first point defect density is not less than 4 times of the second point defect density.

25. The method according to claim 19, wherein, the first threshold is not more than 50%; the second threshold is 1/50˜ 1/10 of the first threshold; the third threshold is 1/20˜ 1/10 of the second threshold and the fourth threshold is 1/20˜ 1/10 of the second threshold.
